(19) United States
(12) Patent Application Publication
(10) Pub. No.: US 2004/0137235 A1
(43) Pub. Date: Jul. 15, 2004

(54) Coated glass sheet

(76) Inventors: Thomas Paul, Herne (DE); Axel Noethe, Castrop-Rauxel (DE); Dieter Mueller, Gelsenkirchen (DE); Michael Rissmann, Haltern (DE); Heinz Hoelscher, Datteln (DE)

Correspondence Address: Donald A Schurr, Marshall & Melhorn, 8th Floor, Four Seagate, Toledo, OH, 43604, US

(21) Appl. No.: 10/473,021

(22) PCT Filed: Mar. 26, 2002
(86) PCT No.: PCT/EP02/03375

(30) Foreign Application Priority Data
Mar. 27, 2001 (DE) 101 15 196.9

(51) Int. Cl. B32B 17/06; C23C 14/32

(52) U.S. Cl. 428/432; 428/434; 204/192.26; 204/192.27; 204/192.28

(57) ABSTRACT

The use of a layer comprising a suboxidic indium oxide as an embedding layer above and/or below a light transmitting silver layer provides a coated glass substrate which can be toughened and/or bent. The preferred suboxidic oxide is indium tin oxide. The coating may comprise one or more silver layers. The bent or toughened coated glass are suitable for use e.g. in vehicle glazings and architectural glazings.

The invention concerns a glass sheet which is useful as an intermediate product for the manufacture of a thermally toughened and/or bent glass sheet provided with a coating which comprises at least one series of layers comprising

a light-transmitting silver layer,

a lower embedding layer disposed below the silver layer and

a suboxidic upper embedding layer disposed above the silver layer.

It furthermore concerns a process for the manufacture of a glass sheet of this kind and a process for manufacturing from this intermediate product a thermally toughened and/or bent glass sheet with a solar control and/or low-e coating.

Glass sheets which are toughened to impart safety properties and/or are bent are required for a large number of areas of application, for example for architectural or motor vehicle glazings. It is known that for thermally toughening or bending glass sheets it is necessary to heat the glass sheets to a temperature near or above the softening point of the glass used and then either to toughen them by rapidly cooling them down or to bend them with the aid of bending means. The temperatures necessary for this are typically around 620±50° C. Difficulties can arise with this if these glass sheets are to be provided with coatings, particularly with coatings comprising at least one silver-based functional layer, e.g. to impart solar control and/or low-e properties. Such coatings are not of themselves heat-resistant. Although it is fundamentally possible to apply such coatings to the glass sheet after the thermal treatment has taken place, this is not without disadvantages.

A number of experiments has been conducted in the past to develop coatings with at least one light-transmitting silver-based functional layer which can be applied to flat glass sheets and then subsequently subjected to a thermal treatment step, in particular a toughening and/or bending process, without damaging the coating.

DE 36 28 057 A1 discloses a heat-resistant coating in the form of a three-layer system consisting of a lower embedding layer of ZnO to which Al₂O₃ has been added, a silver layer and an upper embedding layer, likewise of ZnO with added Al₂O₃. The two completely oxidised metal oxide layers are produced from metal oxide targets by means of DC cathode sputtering in a coating atmosphere containing 0-20 vol % oxygen. The process is carried out such that during the manufacture of the coating, even without the barrier layer usually provided, the silver layer comes into as little as possible contact with oxygen.

A bendable and/or toughenable glass sheet with a coating comprising a series of layers comprising a light-transmitting silver layer and two metallic embedding layers is known from EP 0 229 921 A1. The transition metals Ta, W, Ni and/or Fe are specified as materials for the embedding layers.

A bendable and/or toughenable glass sheet with a coating comprising a series of layers comprising a light-transmitting silver layer and two embedding layers is known from EP 0 233 003 A1, on which the invention is based. The transition metals Al, Ti, Zn, Ta and/or Zr are specified as materials for the embedding layers. Although according to this publication it is provided for that the embedding layers be produced as far as possible without contact with oxygen, suboxides (=substoichiometric oxides) of the mentioned metals may also be used, if it is ensured that the embedding layers evidence an oxygen deficit sufficient to absorb oxygen diffusing into the coating during the heat treatment and thereby to protect the silver layer.

EP 0 761 618 A1 likewise discloses a bendable and/or toughenable glass sheet with a coating comprising at least one series of layers comprising a silver layer and two embedding layers. According to this publication the embedding layers are selected and dimensioned so as to be capable of absorbing oxygen to a sufficient degree. Furthermore, the silver layer is sputtered in an oxygen-containing coating atmosphere. Metals, metal alloys, suboxides, nitrides or suboxidic oxinitrides whose affinity for oxygen is particularly high are specified as materials for the embedding layers. Mentioned specifically are Ti, Al, W, Ta, Zr, Hf, Ce, V, Ni, Cr, Zn, Nb, their alloys, suboxides, nitrides or suboxidic nitrides.

EP 0 963 960 A1 teaches in the same context the use of embedding layers comprising suboxides of alloys of two metals. The only specific example mentioned is Ni—Cr suboxide. It has been found that, if embedding layers consisting of NiCr suboxides are used, either in the case of very thick embedding layers the light transmittance of the finished product leaves something to be desired or in the case of thin embedding layers during the heat treatment an undesirably high light scatter component of the transmitted light (=haze) occurs, indicating partial destruction of the silver layer.

Coatings are known from other contexts where provision is made on both sides of a silver layer for layers consisting of completely oxidised ITO (indium-tin oxide) (DE 33 16 548 A1, EP 0 599 071 A1, EP 0 378 917 A1, DE 27 50 500 A1, DE 37 04 880 A1, DE 195 33 053 A1). Some of the known coatings are heat-treated at temperatures of up to approximately 300° C. to reduce the surface resistance of the silver layer. The known coatings are however not heat-resistant at temperatures necessary for the bending or toughening of glass sheets.

The invention is based on the technical problem of specifying a glass sheet with a heat-resistant coating of the kind stated at the beginning which can be used as an intermediate product for the manufacture of a thermally toughened and/or bent glass sheet with a solar control and/or low-e coating. The must be economic to produce and permit the manufacture of thermally toughened and/or bent glass sheets with a high light transmittance and low emissivity and/or with good solar control properties, i.e. low energy transmittance combined with high light transmittance. At the same time the haze value in transmission of the coated and heat-treated glass sheet must be as small as possible. The coating must moreover be sufficiently chemically and mechanically resistant to be able to withstand storage and the necessary transfers and, if necessary, cleaning processes applied to the coated intermediate product before the heat treatment without elaborate protective measures. The solution to the problem is the subject of claim 1. Advantageous further developments are set out in subclaims 2 to 18. From a second aspect the invention provides an improved process for the manufacture of a thermally toughened and/or bent glass sheet with a solar control and/or low-e coating. As regards the process the solution to the problem is set out in claims 20 to 32. The products of such processes provide a further aspect of the invention and the use of the coated glass of claims 1 to 18 as an intermediate for the production of a thermally toughened and/or bent glass sheet provides another aspect of the invention.

Surprisingly it is possible by using an upper embedding layer which comprises (consists mainly of) a suboxide of indium or of an indium-based alloy and which has a thickness of at least 3 nm in a coating which comprises one or several of these series of layers to make the coating sufficiently heat-resistant such that the silver layer(s) withstand(s) usual toughening and/or bending processes. The lower embedding layer should preferably likewise comprise such suboxide of indium or of an indium-based alloy.

Generally it is preferred to use an indium-tin suboxide for the upper and the lower embedding layer. Particularly good results are obtained if the atomic ratio of indium to the minority additive tin in the upper and possibly the lower embedding layer is between 80:20 and 99:1, and preferably approximately 90:10. Indium-tin oxide layers with such atomic ratios are widely used for conductive electrode coatings. This has the advantage that the materials needed for manufacture of the coating, particularly targets for magnetron cathode sputtering, are available in sufficient quantity. It is however also possible to use a suboxide of pure indium, a suboxide of an indium-cerium alloy, cerium being preferably present in the alloy in an amount of up to about 20 atomic percent, an indium-tin-cerium suboxide or a suboxide of other indium-based alloys. If a suboxide of an indium-based alloy is used rather than a suboxide of pure indium the minority content shall as a rule amount to not more than 20 atomic percent.

The oxygen deficiency and the thickness of the upper embedding layer are preferably adjusted so that during a subsequent thermal toughening and/or bending process the surface resistance of the coating remains constant or decreases, the light transmittance of the coated glass sheet increases and the haze value of the coated glass sheet does not exceed 0.5%.

The increase in light transmittance, which is in most cases several percent, is caused here at least partly by the oxidisation of the suboxidic embedding layer(s), whereas the remaining constant or the usually occurring decrease of the surface resistance of the coating indicate that the layer(s) of silver withstand(s) the heat treatment. Glass sheets coated in accordance with the invention moreover evidence after heat treatment very low values for the haze value in transmission. In the case of the coatings produced according to this invention this is regularly clearly less than 0.5% and mostly in the region of only approximately 0.1%. Larger increases in the haze value are a good early indicator that the coating is beginning to be destroyed.

The oxygen deficiency of the embedding layer(s) are preferably adjusted so that during thermal toughening and/or bending they oxidise as fully as possible without losing their protective function for the silver layer during heat treatment. Experience shows that this is normally the case if the imaginary part of the refractive index n+ik of the embedding layer(s) at a wavelength of 450 nm after the completion of the low-e and/or solar control coating is higher than 0.01, preferably at least 0.04, and after a subsequent thermal toughening and/or bending process is lower than 0.01.

The measured value of the refractive index at a wavelength of 450 nm has proved particularly well suited to the characterisation of suboxidic layers according to this invention. The imaginary part of the refractive index of suboxides of indium or of indium-based alloys like indium-tin is clearly higher at the lower limit of the visible spectral region than at higher wavelengths so that it is easier to measure at low wavelengths like, for example, 450 nm. In the case of fully oxidised, i.e. in the visible spectral range practically absorption-free, indium oxide or indium-based alloy oxide layers the imaginary part of their refractive index in the entire visible spectral range is clearly lower than 0.01.

Although in many cases embedding layers of a suboxide of indium or of an indium-based alloy only about 3 nm thick suffice to protect the silver layer during heat treatment, it has been found that coatings where at least the upper embedding layer has a thickness of approximately 10 nm or more, also withstand heat treatments of a longer duration and/or at higher temperatures without damage. Here it has been found that thicknesses greater than approximately 10 nm do not produce any substantial improvement in heat resistance. In the case of relatively thin embedding layers of a suboxide of indium or of an indium-based alloy experience shows that their oxygen deficiency must be set somewhat higher than that of thicker layers in order to impart sufficient heat resistance to the coating. Surprisingly the beneficial effect of the embedding layers according to the invention seems, however, to be based less on their ability to prevent oxygen diffusion to the silver layer by acting as a buffer or barrier layer, as might be assumed from prior publications in this context. The inventors assume rather that the particularly good protective effect of the suboxidic embedding layers is based on the fact that due to their oxidisation and the associated volume increase boundary surface tensions are set up between the embedding layer and the silver layer which effectively prevent an undesirable agglomeration of the silver atoms during the heat treatment. The magnitude of these boundary surface tensions is apparently particularly favourable in the case of embedding layers comprising suboxides of indium or of-indium-based alloys, especially of indium-tin suboxide, compared to other known materials. Favouring this assumption is the fact that the heat-resistance of coatings according to the invention is comparatively independent of the duration of the heat treatment and that, as already mentioned, the protective effect of the embedding layers according to the invention does not appreciably increase beyond a certain thickness. With a smaller layer thickness the forces acting on the silver layer from the embedding layer(s) decrease, which process is apparently compensated for to a certain extent by the previously mentioned increase of the oxygen deficit.

For the lower embedding layer some of the materials, particularly metals or metal suboxides, of the kind known from the above mentioned earlier publications in this context can as a general principle also be used. In certain cases, particularly at low temperatures or with a short duration of the heat treatment and with the use of relatively thick upper embedding layers it may even be possible to use a fully oxidised lower embedding layer. It has, however, proved particularly advantageous if the lower embedding layer is also produced from suboxides of indium or of indium-based alloys in a thickness of at least 3 nm. Coatings with such series of layers are distinguished not only by a particularly high chemical resistance but can also be produced particularly economically.

It is within the scope of the invention to produce the embedding layers in such a thickness that they already act as anti-reflection layers for the silver layer(s) without additional dielectric layers. An improved optical adaptation and an optimisation of the coating process is, however, then possible, if the coating comprises at least one further dielectric layer comprising a material suitable for this purpose, in particular comprising one or more of the oxides of Sn, Ti, Zn, Nb, Ce, Hf, Ta, Zr, Al and/or Si and/or of nitrides of Si and/or Al. It goes without saying that these layer materials can contain in the known way additives which modify their properties and/or facilitate their manufacture, e.g. doping agents or other reactive gases, as in the case of the oxides in particular of nitrogen. It has, however, been found that within the scope of the invention as a rule the use of oxidic dielectric layers is to be preferred to that of oxinitrides or nitrides. The optical thickness of any additional dielectric layers will normally be adjusted so that together with the embedding layers they reduce reflection by the silver layer(s) as much as possible. In particular cases, for example if low energy transmission is aimed at, it may be desirable for the additional dielectric layers to be light-absorbent. As a rule these will however be selected so as to diminish the light transmittance of the coating as little as possible.

The light-transmitting silver layer will normally consist only of silver without other additives, as is usually the case in the area of low-e and/or solar control coatings. It is, however, within the scope of the invention to modify the properties of the silver layer by adding doping agents, alloy additives or the like, as long as the properties of the silver layer necessary for its function as a highly light-transmitting and low light-absorbent IR-reflective layer are not substantially impaired thereby. If within the scope of the invention silver layers are referred to, this regularly also includes layers modified in this way. The thickness of the silver layer(s) depends upon the desired optical properties. In the case of highly light-transmissive low-e coatings or solar control with a single silver layer their thickness will typically be approximately 6-15 nm, while the total thickness of all silver layers in the case of multiple-silver solar control coatings is typically approximately 12-30 nm.

It is within the scope of the invention to use several series of layers comprising a lower embedding layer, a silver layer and an upper embedding layer in order to optimise the optical properties of the solar control and/or low-e coating for the respective application. In these cases preferably exclusively such series of layers are used in the coating where the upper and preferably also the lower embedding layers each incorporate the thickness and chemical composition of a layer comprising a suboxide of indium and/or of an indium-based alloy according to the invention. If several such series of layers according to the invention are used within a coating, the coating can as a general principle be so designed that the upper embedding layer of one series of layers is at the same time the lower embedding layer of the next series of layers. As a rule, however, at least one further dielectric layer which together with the two above mentioned embedding layers acts as a reflection-reducing Fabry-Perot separation layer between the respective silver layers will be provided for between the upper embedding layer of the one series of layers and the lower embedding layer of the next series of layers.

In order to further increase the scratch-resistance of the coating a thin adhesion-promoting layer of e.g. Cr, NiCr, Ni, Zr and/or Ti or high-grade steel or their suboxides can be provided, preferably between the silver layer and the upper embedding layer. Adhesion-promoting layers of this kind are known. Since, as metal or suboxidic layers, they absorb light in the visible spectral range, their thickness is preferably within the range of only a few nanometers, usually at most approximately 3 nm or less, in order to reduce the light transmittance of the coating as little as possible. Within the scope of the invention the thickness of such adhesion promoting layers must for this reason in every case be clearly less than the thickness of the respective adjacent embedding layer.

Finally, it is within the scope of the invention to provide the coating with a thin metal oxide-, metal oxinitride- or metal nitride-based outer protective layer in order to further increase its mechanical and/or chemical resistance. The thickness of such protective layers is likewise usually in the range of only a few nanometers. Suitable materials for such protective layers are in particular TiO₂, SiO₂ or Si₃N₄.

The invention is not limited to a certain production process for the coating. However, it is particularly suited to solar control and/or low-e coatings where at least one series of layers comprising a lower embedding layer, a silver layer and an upper embedding layer is applied by means of the magnetron cathode sputtering method which can be used particularly economically for the large-surface coating of glass sheets. The entire coating is preferably produced here by means of magnetron cathode sputtering, before the coated glass sheet is subjected to the heat treatment. In this case the suboxidic embedding layers are very preferably produced by the sputtering of targets comprising a suboxide of indium or of an indium-based alloy in a coating atmosphere which is inert or comprises only little oxygen. Alternatively, this can be done by the sputtering of indium or indium-based alloy targets in an oxygen-containing atmosphere. The important thing is that in both cases the coating process is carried out by setting up suitable coating conditions so that the oxygen deficit aimed at in accordance with the invention is achieved. Care should be taken by setting up suitable coating conditions that in every case the upper embedding layers are still suboxidic even after the completion of the coating and do not already fully oxidise during the application of further sub-layers of the coating.

It has been found that the coating process is clearly more stable if suboxidic targets are used and the desired oxygen deficit of the suboxidic embedding layers is markedly easier to set than if indium or indium-based alloy targets are used. Here, surprisingly, it is not essential that the oxygen deficit of the target is very precisely specified. What is apparently decisive for the improved controllability of the sputtering process is merely that there is actually an appreciable oxygen deficit in the oxidic target.

Particularly from the point of view of process technology it is advantageous if both the upper and the lower embedding layer consist equally of a suboxide of indium or of an indium-based alloy, preferably of a suboxide of indium-tin and/or indium cerium, both preferably being sputtered from suboxidic targets in a low-oxygen coating atmosphere and in particular in a coating atmosphere without the addition of oxygen.

The invention is further explained in the following with the aid of examples and a drawing:

The following are represented in diagrammatic form:

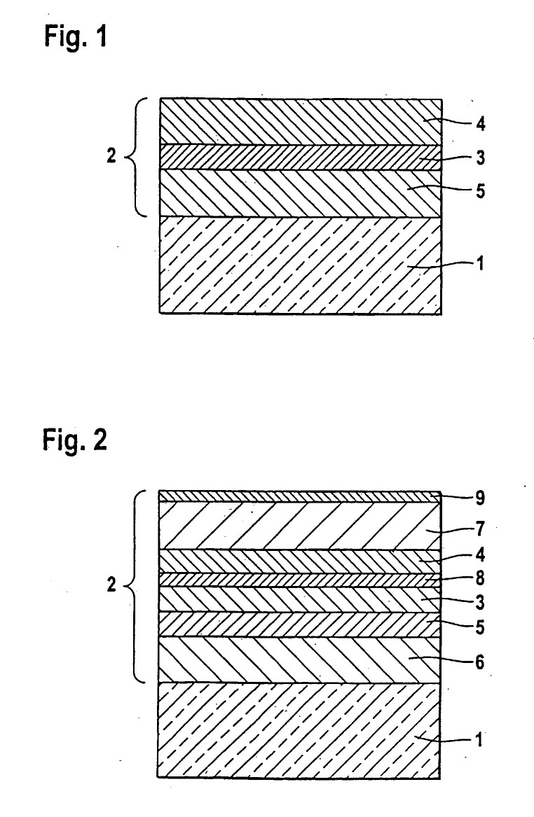

FIG. 1 a first embodiment of the invention in its simplest form where the coating precisely comprises one series of layers according to the invention; and

FIGS. 2-5 further embodiments of the invention.

FIG. 1 shows in a non-scale sectional view a glass sheet 1 with a coating 2. The coating 2 comprises a series of layers according to the invention which series of layers comprises a light-transmitting silver layer 3, an upper embedding layer 4 and a lower embedding layer 5. The two embedding layers 4, 5 have optical thicknesses such that they act as anti-reflection layers for the silver layer 3. They consist of a suboxide of indium or of an indium-based alloy, the oxygen deficit of which is preferably set such that the imaginary part k of the complex refraction index n+ik of both embedding layers 4, 5 at a wavelength of 450 nm is higher than 0.01 after the completion of the coating 2 and lower than 0.01 after a subsequent thermal toughening and/or bending process.

The coating 2 shown in FIG. 1 represents the simplest embodiment of the invention. The coating 2 can, as explained above and as can be seen from the following examples, be supplemented with further layers in order to further optimise its properties. The coating 2 is an intermediate coating to be transformed to a low-e and/or solar control coating during a subsequent thermal treatment of the coated glass sheet 1.

The other figures will be explained in greater detail with the aid of the examples. Values stated for the light transmittance of coated glass sheets in the examples derive from measurements according to ISO 9050 (D65). The measured values for the haze values in transmittance are values obtained in accordance with ASTM D1003.

### EXAMPLE 1 (FIG. 2)

The following series of layers was applied to a 3.2*6 m², 4 mm thick float glass sheet 1 by the magnetron cathode sputtering method in an in-line coating unit:

a lower dielectric layer 6 consisting of TiO₂ (12 nm),

a lower embedding layer 5 consisting of a suboxide of indium-tin (suboxidic ITO) (10 nm),

a silver layer 3 (10 nm),

an adhesion promoting layer 8 consisting of NiCr (3 nm),

an upper embedding layer 4 consisting of suboxidic ITO (10 nm),

an upper dielectric layer 7 consisting of SnO₂ (31 nm) and

an outer protective layer 9 consisting of TiO₂ (3 nm).

The TiO₂ layers 6, 9 are sputtered in an Ar/O₂ atmosphere with the aid of twin targets and using the medium-frequency sputtering method. The suboxidic ITO layers 4, 5 are sputtered by the DC cathode sputtering method with the aid of suboxidic ITO targets in an Ar atmosphere without oxygen addition. Also the silver layer 3 and the NiCr layer 8 are each sputtered in an oxygen-free Ar atmosphere. The SnO₂ layer 7 is sputtered in a reactive Ar/O₂ atmosphere.

The suboxidic ITO layers 4, 5 according to the invention both have a complex refractive index of which the real part n decreases from 2.23 at 380 nm to 1.94 at 780 nm and the imaginary part k decreases from 0.12 at 380 nm to 0.04 at 780 nm. At 450 nm k has a value of 0.08.

The coated float glass sheet 1 has a light transmittance of 78% after the completion of the coating 2. The surface resistance of the coating 2 is 5.8 Ω (means actually Ω/□).

Several 50*100 cm² sheets are then cut out of the float glass sheet. The edges of the glass sheets are seamed and the glass sheets then passed through a toughening oven.

After the thermal toughening the coated glass sheets have a light transmittance of 84.5%, and the surface resistance of the low-e coating is only 4.2 Ω. A value of less than 0.2% is obtained for the haze value. The previously suboxidic ITO layers 4, 5 are practically absorption-free; the imaginary part of their refractive index after heat treatment is clearly lower than 0.01 (at 450 nm). If each of the toughened glass sheets with the low-e coating is processed with a further, uncoated glass sheet to form an insulating glass unit with the coating facing towards the interspace between the sheets, the light transmittance of the insulating glass unit is 76%. With an interspace between sheets of 16 mm and an argon filling the insulating glass sheets have a k value of just 1.1 W/m²K (DIN EN 673).

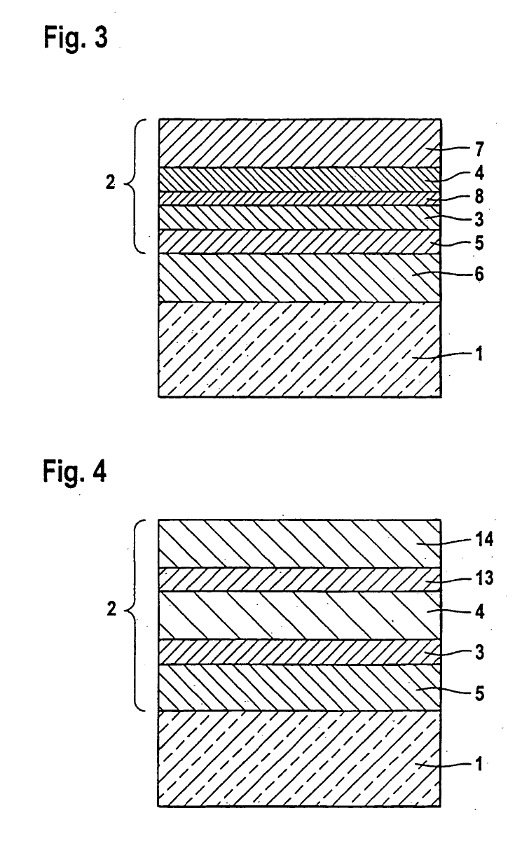

### EXAMPLE 2 (FIG. 3)

The following series of layers was applied consecutively to a 3.2*6 m², 4 mm thick float glass sheet 1 by the magnetron cathode sputter method in an in-line coating unit:

a lower dielectric layer 6 consisting of SnO₂ (25 nm),

a lower embedding layer 5 consisting of suboxidic ITO (10 nm),

a silver layer 3 (9 nm),

an adhesion promoting layer 8 consisting of NiCr (3 nm),

an upper embedding layer 4 consisting of suboxidic ITO (10 nm) and

an upper dielectric layer 7 consisting of SnO₂ (25 nm).

The embedding layers 4, 5 of suboxidic ITO are sputtered with the aid of suboxidic ITO targets in an Ar atmosphere without oxygen addition by the DC cathode sputtering method. Also the silver layer 3 and the NiCr layer 8 are each sputtered in an oxygen-free atmosphere. The SnO₂ layers 6, 7 are sputtered in a reactive Ar/O₂ atmosphere.

The coated float glass sheet 1 has after the completion of the coating 2 a light transmittance of 70.5%. The surface resistance of the coating 2 is 8.1 Ω. The imaginary part of the refractive index of the ITO layers 4, 5 matches that of example 1.

Several 50*100 cm² sheets are then cut from the float glass sheet. The edges of the glass sheets are seamed and the glass sheets then passed through a toughening oven.

After toughening the coated glass sheets have a light transmittance of 84%, and the surface resistance of the low-e coating is only 6.2 Ω. A haze value of less than 0.2% is obtained. The previously suboxidic ITO layers 4, 5 are practically absorption-free in the visible spectral range; the imaginary part of their refractive index after heat treatment is clearly below 0.01 (at 450 nm).

### EXAMPLE 3 (FIG. 4)

A 10*10 cm², 2 mm thick float glass sheet 1 is fed into a laboratory coating unit. A lower embedding layer 5 consisting of suboxidic ITO with a thickness of approximately 40 nm is then sputtered with argon sputter gas without oxygen addition from a ceramic ITO target. A first, 12 nm thick silver layer 3 is then applied in an oxygen-free atmosphere. A further suboxidic ITO layer 4 (80 nm), a second silver layer 13 (12 nm) and a third suboxidic ITO layer 14 (40 nm) are applied, as previously described, consecutively to the first silver layer 3. The glass sheet 1 so coated has a light transmittance of 39%, and the coating 2 has a surface resistance of 3.5 Ω.

The second ITO layer 4 is at the same time the upper embedding layer for the first silver layer 3 and lower embedding layer for the second silver layer 13. It has a thickness such that it acts as a dereflecting Fabry-Perot separating layer for the two silver layers 3, 13.

The coated glass sheet is placed in an oven heated to 650° C. and taken out again after 10 minutes. Its light transmittance after this heat treatment is 80%, and the coating has a surface resistance of 1.8 Ω. A haze value of less than 0.2% is obtained.

In a variant the suboxidic ITO layers 4, 5, 14 are sputtered in an atmosphere containing mainly Ar to which a small amount of oxygen is added (4 sccm). This oxygen addition is so small that the imaginary part of the refractive index of the suboxidic ITO layers 4, 5, 14 at 450 nm is more than 0.01. The-light transmittance of the coated glass layer 1 is after the completion of the coating 2 and before heat treatment 53%. The surface-resistance of the coating 2 is 3.3 Ω.

After heat treatment a light transmittance of 80% is obtained for the toughened glass sheet with low-e coating and a surface resistance of 1.8 Ω for the coating. The thermally treated glass sheets evidence no disturbing haze. In both cases the previously suboxidic ITO layers are practically absorption-free in the visible spectral range.

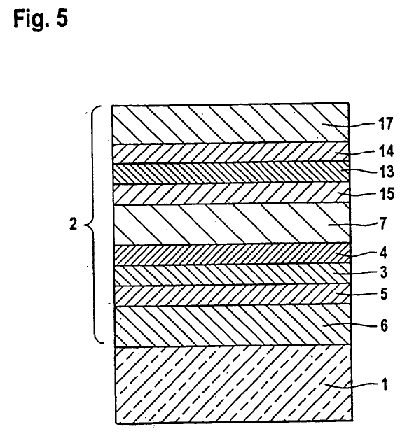

### EXAMPLE 4 (FIG. 5)

Several 2.1 mm thick float glass sheets 1 are fed into a coating unit. The following coating 2 is applied to each of them by the magnetron cathode sputtering method:

a lower dielectric layer 6 consisting of SnO₂ (24 nm)

a lower embedding layer 5 consisting of suboxidic ITO (15 nm)

a first silver layer 3 (7 nm)

a first upper embedding layer 4 consisting of suboxidic ITO (15 nm)

a middle dielectric layer 7 consisting of SnO₂ (66 nm)

a second lower embedding layer 15 consisting of suboxidic ITO (15 nm)

a second silver layer 13 (8 nm)

a second upper embedding layer 14 consisting of suboxidic ITO (15 nm)

an upper dielectric layer 17 consisting of SnO₂ (20 nm).

The SnO₂ layers are sputtered in a reactive Ar/O₂ atmosphere, and the ITO layers are sputtered from a suboxidic ITO target in an Ar atmosphere. The silver layers are sputtered in an Ar atmosphere.

The light transmittance of the coated glass sheets 1 is after the completion of the coating 2 66.6%, and the surface resistance of the coating 2 is 4.7 Ω. The haze value is 0.11%.

The coated glass sheets 1 are exposed to a temperature of 650° C. in an oven for 5 minutes, a part of the glass sheets 1 is bent under the force of gravity, another part is freely suspended in a grip fixture and not formed.

The following measured values are obtained from the flat glass sheets after thermal treatment: Light transmittance 77.6%, surface resistance of the coating 2.7 Ω, haze value 0.12%. The measured values for the bent glass sheets are of the same order.

### COMPARATIVE EXAMPLE 1

A double silver coating stack with the layer sequence SnO₂ (29 nm)/ITO (10 nm)/Ag (8 nm)/ITO (10 nm)/SnO₂ (76 nm)/ITO (10 nm)/Ag (8 nm)/ITO (10 nm)/SnO₂ (25 nm) is applied to 10*10 cm², 2 mm thick float glass sheets in a laboratory coating unit. In contrast to the coating according to example 4, however, the four ITO layers are produced by sputtering from a metallic indium-tin target in an Ar/O₂ atmosphere. The oxygen flow is adjusted such that the resulting ITO layers are completely oxidised and evidence no absorption, so that the imaginary part of their refractive index at 450 nm is less than 0.01. This is achieved in the coating unit by setting an oxygen flow rate of 22 sccm O₂ with a sputtering power of 300 W.

The glass sheet so coated is heated in a laboratory oven to 650° C. for 10 min. The light transmission rises slightly from 80 to 81% during the heat treatment. The surface resistance decreases slightly from 3.0 Ω to 2.7 Ω. However, this glass sheet evidences after heat treatment a high haze value of more than 0.5%, so that it would not be marketable as, for example, a windscreen for motor vehicles due to the low haze value required for this.

### COMPARATIVE EXAMPLE 2

A 3.2*6.0 m², 4 mm thick float glass sheet is fed into an in-line coating unit. A SnO₂ layer (35 nm), a completely oxidised ITO layer (3 nm), a silver layer (8 nm), a NiCr layer (3 nm), a further completely oxidised ITO layer (3 nm) and a SnO₂ layer (35 nm) are then applied to it consecutively. The ITO layers are sputtered from a metallic indium-tin target in an Ar atmosphere such that they evidence practically no absorption in the visible spectral range.

10*10 cm² pieces of this float glass sheet are heated in a laboratory oven to 650° C. for 10 min. After the heat treatment these glass sheets evidence high light diffusion (haze value above 1.2%). Whereas the light transmittance of the coated glass sheets of 85% does not change appreciably during the heat treatment, the surface resistance increases from 8 to 12.5 Ω. These glass sheets are therefore not suitable for use as low-e or solar control sheets.

It goes without saying that the application of the invention is not restricted to the layer sequences of the examples. It is particularly within the scope of the invention to use other indium-based materials than suboxidic ITO for the upper and lower embedding layers, especially suboxides of indium, suboxides of indium-cerium and suboxides of indium-tin-cerium, as long as indium is the majority partner in the alloys used. It is furthermore within the scope of the invention to use other materials than SnO₂ for the dielectric layers or to employ different materials for the dielectric layers employed in a coating—if provided for. The fact that a layer thickness of about 10 nm or less for the upper and, if necessary, lower embedding layer(s) of suboxidic ITO suffices to effectively protect the silver layer(s) enables the production of a large number of layer systems which, depending upon the application, are optimised by suitable choices of thickness and material without deviating from the basic idea of the invention.

1. Glass sheet useful as an intermediate product for the manufacture of a thermally toughened and/or bent glass sheet provided with a coating (2) which comprises at least one series of layers comprising
a light-transmitting silver layer (3, 13),
an lower embedding layer (5, 15) disposed below the silver layer (3, 13) and
a suboxidic upper embedding layer (4, 14) disposed above the silver layer (3, 13),
characterized in that
the upper embedding layer (4, 14) comprises a suboxide of indium or of an indium-based alloy and is at least 3 nm thick.

2. Glass sheet according to claim 1, characterised in that the upper embedding layer (4, 14) comprises a suboxide of an indium-based alloy in which the atomic ratio of indium to the minority additive is between 80:20 and 99:1.

3. Glass sheet according to claim 1 or 2, characterised in that the upper embedding layer (4, 14) comprises a suboxide of indium-tin and/or of indium-cerium.

4. Glass sheet according to one of the foregoing claims, characterised in that the oxygen deficit and the thickness of the upper embedding layer (4, 14) are set such that during a subsequent thermal toughening and/or bending process the surface resistance of the coating (2) remains constant or decreases, the light-transmittance of the coated glass sheet (1, 2) increases and the haze value of the coated glass sheet (1, 2) does not exceed 0.5%.

5. Glass sheet according to one of the foregoing claims, characterised in that the oxygen deficit of the upper embedding layer (4, 14) is set such that the imaginary part of the complex refractive index of the upper embedding layer (4, 14) at a wavelength of 450 nm after the completion of the coating (2) is higher than 0.01 and after a thermal toughening or bending process is lower than 0.01.

6. Glass sheet according to claim 5, characterised in that the imaginary part of the complex refractive index of the upper embedding layer (4, 14) at a wavelength of 450 nm after the completion of the coating (2) is at least 0.04.

7. Glass sheet according to one of the foregoing claims, characterised in that the lower embedding layer (5, 15) comprises a suboxide of indium or of an indium-based alloy and is at least 3 nm thick.

8. Glass sheet according to claim 7, characterised in that the lower embedding layer (5, 15) comprises a suboxide of an indium-based alloy in which the atomic ratio of indium to the minority additive is between 80:20 and 99:1.

9. Glass sheet according to claim 7 or 8, characterised in that the lower embedding layer (5, 15) comprises a suboxide of indium-tin and/or of indium-cerium.

10. Glass sheet according to one of claims 7 to 9, characterised in that the oxygen deficit of the lower embedding layer (5, 15) is set such that the imaginary part of the complex refractive index of the lower embedding layer (5, 15) at a wavelength of 450 nm after the completion of the coating (2) is higher than 0.01 and after a subsequent thermal toughening or bending process lower than 0.01.

11. Glass sheet according to claim 10, characterised in that the imaginary part of the complex refractive index of the lower embedding layer (5, 15) at a wavelength of 450 nm after the completion of the coating (2) is at least 0.04.

12. Glass sheet according to one of the foregoing claims, characterised in that the coating (2) furthermore comprises at least one dielectric layer (6, 7, 17) disposed below the lower embedding layer (5, 15) and/or above the upper embedding layer (4, 14).

13. Glass sheet according to claim 12, characterised in that the at least one dielectric layer (6, 7, 17) comprises an oxide of Sn, Ti, Zn, Nb, Ce, Hf, Ta, Zr, Al and/or Si and/or a nitride of Si and or Al.

14. Glass sheet according to one of the foregoing claims, characterised in that the coating (2) furthermore comprises at least one thin adhesion promoting layer (8), comprising particularly Cr, Ni, NiCr, Zr and/or Ti or high-grade steel or suboxides of these.

15. Glass sheet according to claim 14, characterised in that the thin adhesion promoting layer (8) is disposed between the silver layer (3, 13) and the upper embedding layer (4, 14).

16. Glass sheet according to one of the foregoing claims, characterised in that the coating (2) comprises a thin outer protective layer (9) comprising a metal oxide, metal oxinitride or metal nitride.

17. Glass sheet according to one of claims 1 to 16, characterised in that the coating comprises more than one series of layers m that the upper embedding layer of a lower series of layers is at the same time the lower embedding layer in relation to an upper series of layers.

18. Glass sheet according to one of claims 1 to 16, characterised in that the coating comprises more than one series of layers and in that the coating comprises at least one dielectric layer (7) disposed between the upper embedding layer of a lower series of layers and the lower embedding layer of an upper series of layers.

19. Process for manufacturing a thermally toughened and/or bent glass sheet with a solar control and/or low-e coating, characterised in that a thermal toughening and/or bending process is carried out at a temperature of 620±50° C. on a intermediate product glass sheet according to one of claims 1 to 18.

20. Process for manufacturing a thermally toughened and/or bent glass sheet with a solar control and/or low-e coating during which process first a coating (2) is applied to a flat glass sheet (1) which coating (2) comprises at least one series of layers applied by magnetron cathode sputtering and comprising at least one light-transmitting silver layer (3, 13), at least one lower embedding layer (5, 15) disposed below the silver layer (3, 13) and at least one suboxidic upper embedding layer (4, 14) disposed above the silver layer (3, 13) and in which process after the completion of the coating (2) the glass sheet (1) is subjected to a thermal toughening and/or bending process, characterised in that the upper embedding layer (4, 14) is applied as a layer which comprises a suboxide of indium or of an indium-based alloy in a thickness of at least 3 nm such that after the completion of the coating (2) the upper embedding layer (4, 14) is still in a suboxidic state.

21. Process according to claim 20, characterised in that the upper embedding layer (4, 14) is applied as a suboxide of an indium-based alloy with an atomic ratio of indium to the minority additive between 80:20 and 99:1.

22. Process according to claim 21, characterised in that the upper embedding layer (4, 14) is applied as a suboxide of indium-tin and/or indium-cerium.

23. Process according to one of claims 20 to 22, characterised in that the oxygen deficit and the thickness of the upper embedding layer (4, 14) are set such that during a subsequent thermal toughening and/or bending process the surface resistance of the coating (2) remains constant or decreases, the light-transmittance of the coated glass sheet (1, 2) increases and the haze value of the coated glass sheet (1, 2) does not exceed 0.5%.

24. Process according to one of claims 20 to 23, characterised in that the upper embedding layer (4, 14) is applied under such coating conditions that the imaginary part of its complex refractive index at a wavelength of 450 nm after the completion of the coating (2) is higher-than 0.01, preferably at least 0.04, and after the thermal toughening or bending process is lower than 0.01.

25. Process according to one of claims 20 to 24, characterised in that the upper embedding layer (4, 14) is produced by sputtering an indium suboxide or indium-based alloy suboxide target, preferably an indium-tin and/or indium-cerium suboxide target, in a coating atmosphere containing little or no oxygen.

26. Process according to one of claims 20 to 24, characterised in that the upper embedding layer (4, 14) is produced by sputtering an indium or an indium-based alloy target, preferably an indium-tin and/or an indium-cerium target, in a coating atmosphere the oxygen content of which is set lower than would be necessary for the production of a completely oxidised layer.

27. Process according to one of claims 20 to 26, characterised in that the at least 3 nm thick lower embedding layer (5, 15) is applied as a suboxide of indium or of an indium-based alloy such that even after production of the coating (2) the lower embedding layer (5, 15) is still in a suboxidic state.

28. Process according to claim 27, characterised in that the lower embedding layer (5, 15) is applied as a suboxide of an indium-based alloy with an atomic ratio of indium to the minority additive between 80:20 and 99:1.

29. Process according to claim 27 or 28, characterised in that the lower embedding layer (5, 15) is applied as a suboxide of indium-tin and/or indium-cerium.

30. Process according to one of claims 27 to 29, characterised in that the lower embedding layer (5, 15) is applied under such coating conditions that the imaginary part of its complex refractive index at a wavelength of 450 nm after production of the coating (2) is higher than 0.01, preferably at least 0.04, and after the thermal toughening and/or bending process is lower than 0.01.

31. Process according to one of claims 27 to 30, characterised in that the lower embedding layer (5, 15) is produced by sputtering an indium or an indium-based alloy suboxide target, preferably an indium-tin and/or indium-cerium suboxide target, in a coating atmosphere containing little or no oxygen.

32. Process according to one of claims 27 to 30, characterised in that the lower embedding layer (5, 15) is produced by sputtering an indium or an indium-based alloy target, preferably an indium-tin and/or indium-cerium target, in a coating atmosphere the oxygen content of which is set lower than would be necessary for the production of a completely oxidised layer.

33. Thermally toughened and/or bent glass sheet with a solar control and/or low-e coating which has been produced by a process according to one of claims 20 to 32.

34. Use of a glass sheet according to one of claims 1 to 18 as an intermediate product for the manufacture of a thermally toughened and/or bent glass sheet with a solar controlled coating.

35. Use of a glass sheet according to one of claims 1 to 18 comprising two or more of said series of layers for the manufacture of a thermally toughened and/or bent glass sheet with a solar control coating.
